(19) United States
(12) Patent Application Publication
(10) Pub. No.: US 2005/0178954 A1
(43) Pub. Date: Aug. 18, 2005

(54) Optical sensor device

(75) Inventor: Yohei Yukawa, Seto-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/052,091

(22) Filed: Feb. 8, 2005

(30) Foreign Application Priority Data
Feb. 18, 2004 (JP) 2004-41905

(51) Int. Cl. H01L 27/00

(52) U.S. Cl. 250/221

(57) ABSTRACT

An optical sensor device includes a luminescence element for emitting ray toward a windshield of a vehicle, and a photoreception element for detecting ray projected thereon. A sensor case is provided for accommodating the photoreception element and the luminescence element, which is activated by a control unit according to a predetermined luminescence pattern. The control unit switches an output of the photoreception element as an output of a rain sensor or an illumination sensor, based on the predetermined luminescence pattern of the luminescence element. Accordingly, the rain sensor and the illumination sensor can share the same photoreception element, thus small-sizing the optical sensor device.

### CROSS REFERENCE TO RELATED APPLICATION

This application is based on Japanese Patent Applications No. 2004-41905 filed on Feb. 18, 2004, the disclosure of which is incorporated herein by reference.

### FIELD OF THE INVENTION

The present invention relates to an optical sensor device including a rain senor and an illuminance sensor, both of which are accommodated in a same sensor case.

### BACKGROUND OF THE INVENTION

Generally, a rain sensor used in a wiper automatic control system for a vehicle is provided with a luminescence element and a photoreception element. The rain sensor is mounted at a windshield (front window) of the vehicle. Thus, the luminescence element emits ray toward the windshield, and the photoreception element detects the ray which is reflected by the windshield and projected onto the photoreception element. Based on a photoreception amount of the photoreception element, a raindrop amount can be detected, referring to JP-2001-99948.

Moreover, an illuminance sensor is also mounted in the vehicle, for example, an auto-light sensor for detecting illumination ray from an upper area with respect to the vehicle and a far-light sensor for detecting illumination ray from an area in front of the vehicle. Thus, corresponding lights of the vehicle can be switched (turned on and off) according to the detected illumination ray.

In this case, the rain sensor and the illuminance sensor are separately provided with the photoreception elements, respectively, then increasing the space occupied by the sensors. Therefore, a sensor case for accommodating the sensors becomes larger.

### SUMMARY OF THE INVENTION

In view of the above problems, it is an object of the present invention to provide a small-sized optical sensor device, in which a rain sensor and an illuminance sensor are accommodated in a same sensor case and share a same photoreception element.

According to the present invention, an optical sensor device includes a luminescence element for emitting ray toward a windshield of a vehicle, and a photoreception element for detecting ray projected thereon. A sensor case is provided for accommodating the photoreception element and the luminescence element, which is activated by a control unit according to a predetermined luminescence pattern. The control unit switches an output of the photoreception element as an output of a rain sensor or an illumination sensor, based on the predetermined luminescence pattern of the luminescence element.

Accordingly, the rain sensor and the illumination sensor, which are arranged in the same sensor case, can share the same photoreception element, thus small-sizing the optical sensor device and reducing a manufacture cost thereof.

Preferably, the photoreception element detects the illumination ray from an upper area with respect to the vehicle, or from an area in front of the vehicle, so that the illuminance sensor is used as an auto-light sensor or a far-light sensor.

More preferably, the optical sensor device is provided with a first photoreception element which is used as the auto-light sensor and a second photoreception element which is used as the far-light sensor. One of the first and second photoreception elements is also used for the rain sensor. The first and second photoreception elements are mounted on a same base plate. Accordingly, the optical sensor device can be further small-sized.

### BRIEF DESCRIPTION OF THE DRAWINGS

Other objects, features and advantages of the present invention will become more apparent from the following detailed description made with reference to the accompanying drawings, in which:

FIG. 1 is a block diagram showing an optical sensor device according to a preferred embodiment of the present embodiment;

FIG. 2 is a schematic diagram showing the optical sensor device according to the preferred embodiment;

FIG. 3 is a graph showing output wave shapes of a luminescence element, a photoreception element, an illuminance sensor and a rain sensor according to the preferred embodiment; and

FIG. 4 is a schematic diagram showing an optical sensor device according to a modification of the preferred embodiment.

### DETAILED DESCRIPTION OF THE PREFERRED EMBODIMENTS

### Preferred Embodiment

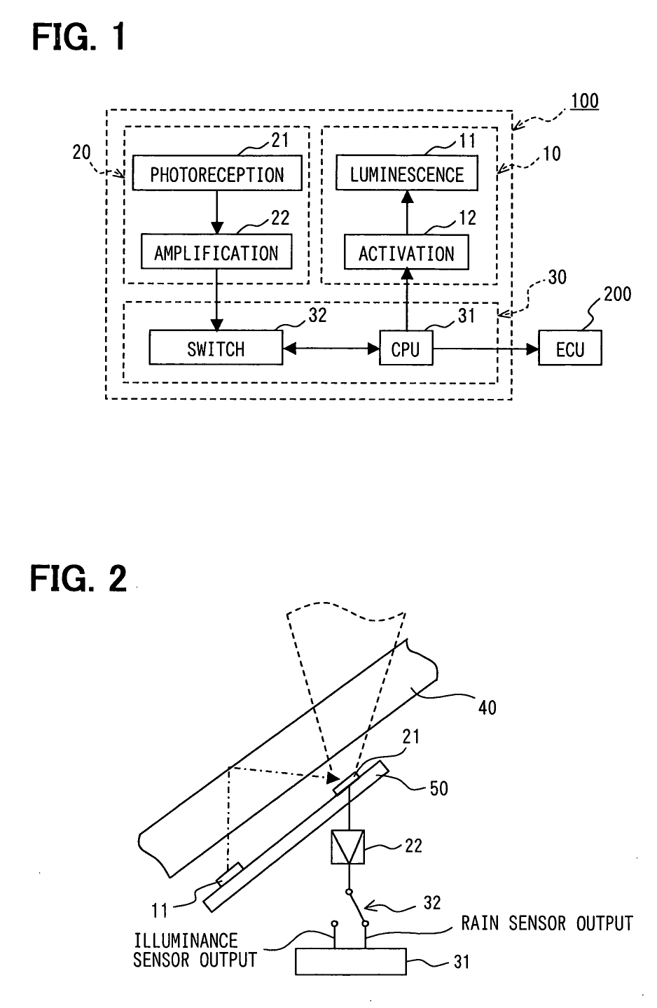

An optical sensor device 100 for a movable apparatus (e.g., vehicle) will be described in the preferred embodiment with reference to FIGS. 1-3.

As shown in FIG. 1, the optical sensor device 100 is provided with a luminescence unit 10, a photoreception unit 20 and a control unit 30, all of which are accommodated in a sensor case (not shown).

The luminescence unit 10 includes a luminescence element 11, and a luminescence activation circuit 12 for activating the luminescence element 11. When the luminescence activation circuit 12 receives a luminescence demand signal from the control unit 30, the luminescence activation circuit 12 will activate (turn on) the luminescence element 11, which is constructed with an infrared luminescence diode, for example. Thus, the luminescence element 11 emits infrared ray (indicated as one point chain line in FIG. 2) toward a front window (windshield) 40 of the vehicle.

The photoreception unit 20 includes a photoreception element 21 and an output amplification circuit 22 for amplifying an output of the photoreception element 21. The photoreception element 21 is constructed with, for example, a photo diode, which is disposed to be capable of detecting both illumination ray from the outside of the vehicle and the infrared ray reflected by an outer surface of the front window 40. That is, a photoreception amount of the photoreception element 21 corresponds to the illumination ray from the outside of the vehicle and the reflected infrared ray from the luminescence element 11.

Therefore, the luminescence element 11 and the photoreception element 21 can function as a rain sensor for detecting a raindrop amount based on the infrared photoreception amount of the photoreception element 21. Corresponding to the detected raindrop amount, wipers of the vehicle is operated. Moreover, the photoreception element 21 can also function as an illuminance sensor (e.g., auto-light sensor) by detecting the illumination ray from the outside of the vehicle. According to the illumination photoreception amount, lights of the vehicle such as headlights are switched. In this embodiment, the luminescence element 11 and the photoreception element 21 are mounted on a same base plate 50.

In this case, detected signals corresponding to the infrared and illumination photoreception amounts of the photoreception element 21 are output to the output amplification circuit 22, which lineally amplifies the detected signals and thereafter outputs them to the control unit 30.

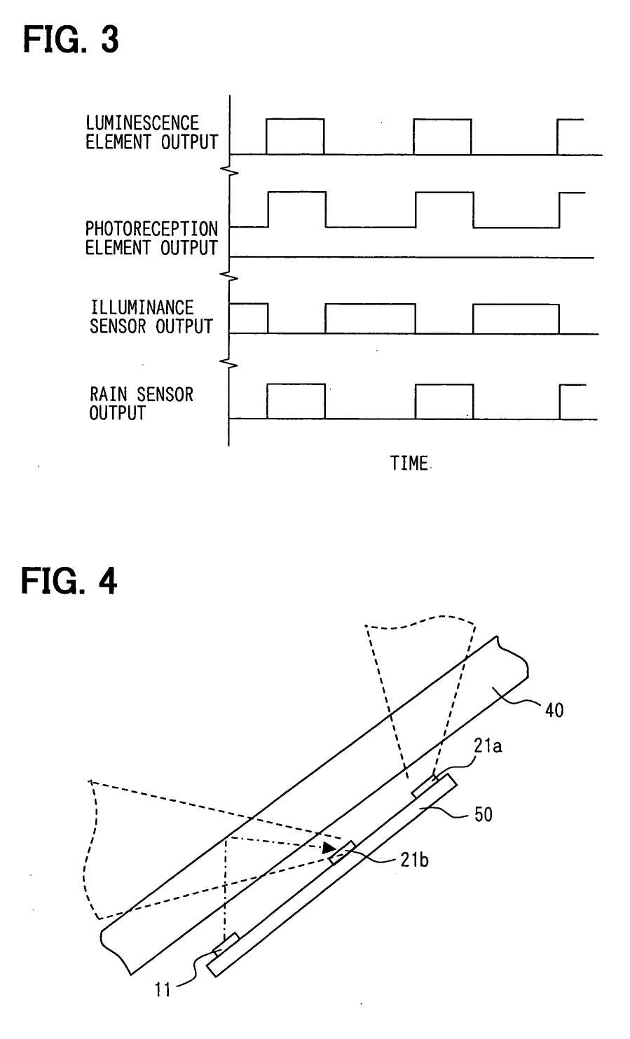

The control unit 30 (e.g., microcomputer) is constructed of a central processing unit (CPU) 31, an interior memory (not shown), an output switch circuit (output switch) 32 and the like. The output switch circuit 32 switches an output of the photoreception element 21 as that of the rain sensor or the illuminance sensor corresponding to a luminescence pattern of the luminescence element 11. The luminescence demand signal to be output to the luminescence activation circuit 12 is periodically generated by the CPU 31, so that the luminescence element 11 is switched (turned on and off) at a predetermined switch pattern having a predetermined switch period (frequency) referring to FIG. 3. The CPU 31 also generates and outputs an output switch signal in synchronization with the luminescence demand signal to the output switch circuit 32. Thus, the output switch circuit 32 switches the output of the photoreception element 21 as that of the rain sensor or the illuminance sensor and sends it to the CPU 31, corresponding to the switch frequency of the luminescence element 11. The CPU 31 receives and processes the detected signals from the output switch circuit 32, then sending them to an ECU (electronic control unit) 200 of the vehicle chassis.

In this optical sensor device 100, the rain sensor and the illuminance sensor are arranged in the same sensor case and share the same photoreception element 21, so that the optical sensor device 100 can be small-sized and a manufacture cost thereof can be reduced.

Next, a control operation of the luminescence unit 10 and the photoreception unit 20 will be described referring to FIGS. 1 and 3. In the case where an ignition SW (ignition switch which is not shown) of the vehicle is ON, the control operation will be started or ended when an auto-wiper SW (auto-wiper switch which is not shown) for controlling the wipers and an auto-light SW (auto-light switch which is not shown) for switching the lights are turned on or off.

In the case where the ignition SW is ON, when the auto-wiper SW and the auto-light SW are turned on, the CPU 31 outputs the luminescence demand signal to the luminescence activation circuit 12, so that the luminescence element 11 is activated corresponding to a predetermined luminescence pattern, for example, as shown in FIG. 3. Meanwhile, the CPU 31 outputs the output switch signal in synchronism with the luminescence demand signal to the output switch circuit 32 of the control unit 30.

When the luminescence element 11 is switched by the luminescence activation circuit 12 at the predetermined frequency according to the luminescence demand signal, the infrared ray will be periodically emitted by the luminescence element 11, then reflected by the front window 40.

Thus, the photoreception element 21 detects the reflected infrared ray, and outputs the signal corresponding to the infrared photoreception amount to the output amplification circuit 22 through a detector circuit (not shown). The output amplification circuit 22 amplifies the photoreception amount signal and outputs it to the output switch circuit 32. Then, the output switch circuit 32 outputs the photoreception amount signal to the CPU 31 as the output of the rain sensor or the illuminance sensor, based on the output switch signal (luminescence pattern of luminescence element 11) generated by the CPU 31.

On the other hand, the photoreception element 21 detects the illumination ray from the outside of the vehicle all the time. When the reflected infrared ray is projected on the photoreception element 21, the output (photoreception amount signal) of the photoreception element 21 will increase. That is, the output of the photoreception element 21 will vary corresponding to the luminescence pattern of the luminescence element 11.

With reference to FIG. 3, the photoreception amount signal of the photoreception element 21 will be outputted as the output of the rain sensor when the luminescence element 11 is ON, that is, the photoreception element 21 is used for the rain sensor. When the luminescence element 11 is OFF, the photoreception amount signal of the photoreception element 21 is outputted as the output of the illuminance sensor, that is, the photoreception element 21 is used as the illuminance sensor.

Then, the CPU 31 will compare the output of the rain sensor or the illuminance sensor with a wiper-activation threshold value and a light-activation threshold value, thereafter outputting a corresponding signal to the ECU 200, which controls a wiper operation system and a light switch system.

As described above, when the luminescence element 11 is ON, the photoreception amount of the photoreception element 21 (used for rain sensor) is a total of the infrared photoreception amount and the illumination photoreception amount. Therefore, before the output of the rain sensor is compared with the wiper-activation threshold value, the CPU 31 calculates the infrared photoreception amount by eliminating the illumination photoreception amount from the total photoreception amount after they are input to the CPU 31. Then, the CPU 31 compares the infrared photoreception amount with the wiper-activation threshold value. In this case, because the luminescence element 11 is switched at the predetermined switch frequency, the illumination photoreception amount of the photoreception element 21 can be calculated based on an output of the photoreception element 21 (used for illuminance sensor) when the luminescence element 11 is turned off immediately before this luminescence.

Instead of the elimination of the illumination photoreception amount from the total photoreception amount, that is, calculation of the output of the photoreception element 21 as the rain sensor, another wiper-activation threshold value can be calculated, which includes the illumination photoreception amount of the photoreception element 21. Thus, the CPU 31 can compare this wiper-activation threshold value with the total photoreception amount of the photoreception element 21 when being used for the rain sensor, so that the ECU 200 determines whether or not the wipers are activated based on the comparison. In this case, the illumination photoreception amount of the photoreception element 21 can be calculated as described above. The multiple threshold values are beforehand set and memorized in the EEPROM of the control unit 30 or the like.

According to this embodiment, the rain sensor and the illuminance sensor can effectively function even sharing the same photoreception element 21.

### Other Embodiment

Although the present invention has been fully described in connection with the first embodiment thereof with reference to the accompanying drawings, it is to be noted that various changes and modifications will become apparent to those skilled in the art.

In the above-described preferred embodiment, the photoreception element 21 is used for the illuminance sensor, which can be not only the auto-light sensor but also a far-light sensor for determining whether or not the vehicle is traveling in a tunnel or down a bridge based on a photoreception amount of illumination ray from an area in front of the vehicle.

As an optical sensor, the far-light sensor can be accommodated in the same sensor case with the rain sensor and the auto-light sensor. For example, as shown in FIG. 4, the photoreception elements 21a and 21b are provided as the auto-light sensor and the far-light sensor, respectively. One of the photoreception elements 21a and 21b is also used as the rain sensor. In FIG. 4, the photoreception element 21b is used as the rain sensor. The infrared ray emitted by the luminescence element 11 and reflected by the front window 40 is indicated by the one point chain line. The photoreception areas of the photoreception elements 21a and 21b (auto-light sensor and far-light sensor) are indicated by the broken line. In this case, the photoreception elements 21a and 21b are mounted at the same base plate 50. Accordingly, the optical sensor device 100 can be small-sized.

Moreover, the illuminance sensor can be also used as a solar radiation sensor for detecting a direction of sun.

Such changes and modifications are to be understood as being within the scope of the present invention as defined by the appended claims.

1. An optical sensor device for a movable apparatus, the optical sensor device comprising:
a rain sensor for detecting a raindrop amount, including:
a luminescence element for emitting ray toward a windshield of the movable apparatus; and
a photoreception element for detecting ray reflected by the windshield; and
a control unit for activating the luminescence element according to a predetermined luminescence pattern, wherein:
the photoreception element also functions as an illuminance sensor for detecting illumination ray from an outside of the movable apparatus; and
the control unit switches an output of the photoreception element as an output of one of the rain sensor and the illumination sensor, based on the predetermined luminescence pattern of the luminescence element.

2. The optical sensor device according to claim 1, further comprising
a sensor case for accommodating the luminescence element and the photoreception element.

3. The optical sensor device according to claim 1, wherein
the photoreception element detects the illumination ray from an upper area with respect to the movable apparatus, so that the illuminance sensor is used as an auto-light sensor.

4. The optical sensor device according to claim 1, wherein
the photoreception element detects the illumination ray from an area in front of the movable apparatus, so that the illuminance sensor is used as a far-light sensor.

5. The optical sensor device according to claim 2, further comprising
a second photoreception element, wherein:
one of the photoreception element and the second photoreception element is used as a far-light sensor to detect the illumination ray from an area in front of the movable apparatus, and the other is used as an auto-light sensor to detect the illumination ray from an upper area with respect to the movable apparatus; and
one of the photoreception element and the second photoreception element is also used for the rain sensor.

6. The optical sensor device according to claim 5, further comprising
a base plate, on which the photoreception element and the second photoreception element are mounted.

7. The optical sensor device according to claim 5, wherein the luminescence element, the photoreception element and the second photoreception element are accommodated in the same sensor case.

8. The optical sensor device according to claim 1, wherein the movable apparatus is a vehicle.

9. An optical sensor device for a vehicle, the optical sensor device comprising:
a rain sensor for detecting a raindrop amount, including:
a luminescence element for emitting ray toward a windshield of the vehicle; and
a photoreception element for detecting ray projected thereon;
a sensor case for accommodating the luminescence element and the photoreception element; and
a control unit for activating the luminescence element according to a predetermined luminescence pattern, wherein:
the photoreception element also functions as an illuminance sensor for detecting illumination ray from an outside of the vehicle;
when the luminescence element is activated to emitting the ray, the control unit switches an output of the photoreception element as an output the rain sensor; and
when the luminescence element is not activated, the control unit switches the output of the photoreception element as an output the illumination sensor.
